(19) United States
(12) Patent Application Publication
(10) Pub. No.: US 2026/0247081 A1
(43) Pub. Date: Aug. 20, 2026

(54) STRAIN-INSENSITIVE STRETCHABLE THERMOACOUSTIC LOUDSPEAKER AND METHOD FOR MANUFACTURING THE SAME

(71) Applicant: UIF (University Industry Foundation), Yonsei University, Seoul (KR)

(72) Inventors: Jongbaeg KIM, Goyang-si (KR); Sangjun SIM, Seoul (KR)

(73) Assignee: UIF (University Industry Foundation), Yonsei University, Seoul (KR)

(21) Appl. No.: 19/530,585

(22) Filed: Feb. 5, 2026

(30) Foreign Application Priority Data
Feb. 19, 2025 (KR) 10-2025-0021442

(51) Int. Cl. H04R 23/00; C01B 32/16; C23C 16/26; H04R 31/00

(52) U.S. Cl. CPC H04R 23/002; C01B 32/16; C23C 16/26; H04R 31/00; C01B 2202/08; C01B 2202/22; C01P 2004/03; C01P 2006/40

(57) ABSTRACT

Disclosed is a strain-insensitive stretchable thermoacoustic loudspeaker comprising: a stretchable polymer substrate; a heating element including a film including bundles of vertically aligned carbon nanotubes (VACNTs) on the stretchable polymer substrate; an electrode part including a first electrode electrically connected to the heating element and a second electrode spaced apart from the first electrode and electrically connected to the heating element; and a power application means for applying alternating current (AC) voltage to the electrode part, wherein the AC voltage is applied to the electrode part such that the heating element thermally oscillates to generate an acoustic wave.

### CROSS-REFERENCE TO RELATED APPLICATION

This application claims priority from Korean Patent Application No. 10-2025-0021442 filed on February 19, 2025 in the Korean Intellectual Property Office, and all the benefits accruing therefrom under 35 U.S.C. 119, the contents of which in its entirety are herein incorporated by reference.

### BACKGROUND

### Field

The present disclosure relates to a stretchable thermoacoustic loudspeaker in which vertically aligned carbon nanotubes (VACNT) are integrated with a stretchable polymer substrate, thereby maintaining stable sound pressure level performance even while being stretched, and a method for manufacturing the same.

### Description of Related Art

Loudspeaker technology plays a key role in various industries such as electronic devices, wearable devices, home appliances, and vehicle audio systems. Conventional electromagnetic loudspeakers generally generate sound through mechanical oscillation using a coil and a diaphragm. Although such a traditional loudspeaker provides relatively excellent sound quality, it is structurally hard and thick, and has a limitation to be applied to a flexible electronic device or a wearable device due to its difficult deformation characteristics.

In order to overcome these limitations, the industry needs a flexible loudspeaker technology. In particular, as applications such as wearable devices, smart clothing, and electronic skin are expanded, loudspeaker technology based on a new principle rather than the conventional mechanical oscillation method is required. Based on this necessity, a thermoacoustic loudspeaker was developed. The thermoacoustic loudspeaker operates in a manner that induces a periodic temperature change of air by using Joule heat generated when a current flows, thereby generating an acoustic wave. Since a mechanical oscillation element is not required, it may be manufactured in a very thin and flexible form, and there is an advantage in that an ultra-light structure may be realized through bonding with a nanomaterial.

However, the conventional thermoacoustic loudspeaker technology has several limitations. Representatively, a stretchable thermoacoustic loudspeaker using a graphene or Kirigami structure has been studied, but there is a problem in that sound pressure level performance is significantly deteriorated while being stretched. For example, in the case of a stretchable thermoacoustic loudspeaker based on a graphene-coated fabric, a sound pressure level reduction of about 40 dB occurs when the stretchable thermoacoustic loudspeaker is stretched by 50%, thus making it difficult to output a sound stably in an actual application. In addition, in the case of the stretchable loudspeaker based on the Kirigami structure, it was successful in maintaining the sound pressure level performance while being stretched, but the stretchability was limited to a maximum of 50% due to the original rigidity of the constituent material thereof.

### SUMMARY

The present disclosure has been devised to overcome the limitations of these conventional technologies. Thus, a technical purpose to be achieved by the present disclosure is to provide a strain-insensitive stretchable thermoacoustic loudspeaker capable of minimizing a decrease in sound pressure level performance even when the stretchable thermoacoustic loudspeaker is stretched by 300% or greater, and a method for efficiently manufacturing the same.

To this end, a technical purpose of the present disclosure is to integrate vertically aligned carbon nanotubes (VACNTs) into a stretchable polymer substrate such that a portion of a strand of the CNT is exposed to the outside out of the substrate, so that efficient heat transfer and stable sound output may be maintained even while high stretchability is achieved.

The purposes of the present disclosure are not limited to the above-mentioned purposes, and other purposes and advantages of the present disclosure that are not mentioned may be understood based on the following descriptions, and will be more clearly understood based on the embodiment of the present disclosure. In addition, it will be readily appreciated that the purposes and advantages of the present disclosure may be realized by means recited in the claims and combinations thereof.

According to an aspect of the present disclosure, provided is a strain-insensitive stretchable thermoacoustic loudspeaker comprising: a stretchable polymer substrate; a heating element including a film including bundles of vertically aligned carbon nanotubes (VACNTs) on the stretchable polymer substrate; an electrode part including a first electrode electrically connected to the heating element and a second electrode spaced apart from the first electrode and electrically connected to the heating element; and a power application means for applying alternating current (AC) voltage to the electrode part, wherein the AC voltage is applied to the electrode part such that the heating element thermally oscillates to generate an acoustic wave.

In accordance with some embodiments of the strain-insensitive stretchable thermoacoustic loudspeaker, the stretchable polymer substrate includes a silicone elastomer.

In accordance with some embodiments of the strain-insensitive stretchable thermoacoustic loudspeaker, the heating element is constructed such that a portion of each of strands of the carbon nanotubes is buried in the stretchable polymer substrate, while the remaining portion thereof is exposed to the outside out of the stretchable polymer substrate.

In accordance with some embodiments of the strain-insensitive stretchable thermoacoustic loudspeaker, the exposed portions of the strands of the carbon nanotubes are entangled with each other.

In accordance with some embodiments of the strain-insensitive stretchable thermoacoustic loudspeaker, each of the first and second electrodes of the electrode part includes a liquid metal including one of gallium (Ga) and eutectic gallium-indium (EGaIn) or a solid metal including one of gold (Au), silver (Ag), platinum (Pt), copper (Cu), aluminum (Al), iron (Fe), chromium (Cr), nickel (Ni), and alloys thereof.

In accordance with some embodiments of the strain-insensitive stretchable thermoacoustic loudspeaker, a structure of the strain-insensitive stretchable thermoacoustic loudspeaker is not deformed even in a state in which the strain-insensitive stretchable thermoacoustic loudspeaker is stretched by 325%, wherein a difference between a sound pressure level (SPL) in a state in which the strain-insensitive stretchable thermoacoustic loudspeaker is not stretched and the SPL in a state in which the strain-insensitive stretchable thermoacoustic loudspeaker is stretched by 150% is maintained at 5 dB or smaller.

According to another aspect of the present disclosure, provided is a method for manufacturing a strain-insensitive stretchable thermoacoustic loudspeaker, the method comprising: a first step of growing bundles of vertically aligned carbon nanotubes on a wafer; a second step of transferring the bundles of the vertically aligned carbon nanotubes onto a stretchable polymer substrate to form a heating element; a third step of removing the wafer from the bundles of the vertically aligned carbon nanotubes transferred to the stretchable polymer substrate; a fourth step of placing a first electrode and a second electrode onto the heating element so as to contact the heating element and to be spaced apart from each other, thereby forming an electrode part; and a fifth step of electrically connecting the electrode part and a power application means capable of applying an AC voltage thereto to each other.

In accordance with some embodiments of the method for manufacturing the strain-insensitive stretchable thermoacoustic loudspeaker, the first step of growing the bundles of the vertically aligned carbon nanotubes on the wafer is performed in a chemical vapor deposition (CVD) process.

In accordance with some embodiments of the method for manufacturing the strain-insensitive stretchable thermoacoustic loudspeaker, the method further comprises providing the stretchable polymer substrate formed by coating an uncured silicone elastomer on a stretchable silicone elastomer substrate.

In accordance with some embodiments of the method for manufacturing the strain-insensitive stretchable thermoacoustic loudspeaker, the coating of the uncured silicone elastomer on the stretchable silicone elastomer substrate is performed in a spin coating process.

In accordance with some embodiments of the method for manufacturing the strain-insensitive stretchable thermoacoustic loudspeaker, the method further comprises curing the uncured silicone elastomer.

In still another aspect of the present disclosure, provided is a strain-insensitive stretchable thermoacoustic loudspeaker manufactured by the method for manufacturing the strain-insensitive stretchable thermoacoustic loudspeaker.

The strain-insensitive stretchable thermoacoustic loudspeaker according to the present disclosure minimizes degradation of the sound pressure level performance even when the stretchable thermoacoustic loudspeaker is stretched by about 325% or greater, and may maintain efficient heat transfer and stable sound output using a structure in which the portion of the strand of the CNT is exposed to the outside out of the substrate.

The method for manufacturing the strain-insensitive stretchable thermoacoustic loudspeaker according to the present disclosure integrates the VACNTs into the stretchable polymer substrate by utilizing a low temperature transfer process, thereby simplifying the manufacturing process and improving compatibility with various stretchable materials.

In addition to the above-described effects, the specific effects of the present disclosure will be described together while describing specific matters for implementing the embodiments of the present disclosure below.

### BRIEF DESCRIPTION OF DRAWINGS

FIG. 1 is a diagram schematically showing a structure of a strain-insensitive stretchable thermoacoustic loudspeaker according to the present disclosure.

FIG. 2 is a diagram comparing operating mechanisms of the loudspeaker according to the present disclosure respectively before and after being stretched with each other.

FIGS. 3A to 3F are diagrams illustrating a process for manufacturing a strain-insensitive stretchable thermoacoustic loudspeaker according to the present disclosure step by step.

FIG. 4 is a view showing a real image of a strain-insensitive stretchable thermoacoustic loudspeaker manufactured according to an embodiment of the present disclosure and a SEM image obtained by photographing bundles of carbon nanotubes of a heating element thereof.

FIG. 5A is a diagram illustrating sound pressure level characteristics (SPL) in a state in which a strain-insensitive stretchable thermoacoustic loudspeaker according to the present disclosure is stretched by from 0% to 150%.

FIG. 5B is a diagram comparing sound pressure level characteristics and allowable strain limits of a strain-insensitive stretchable thermoacoustic loudspeaker according to the present disclosure and a stretchable loudspeaker reported in a previous study with each other.

FIG. 6A is a diagram illustrating a sound pressure level characteristic (SPL) based on operating power of the strain-insensitive stretchable thermoacoustic loudspeaker according to the present disclosure.

FIG. 6B is a diagram illustrating an evaluation of a sound pressure level characteristic (SPL) according to a measurement distance of a strain-insensitive stretchable thermoacoustic loudspeaker according to the present disclosure.

FIG. 7A is a diagram illustrating an evaluation of a sound pressure level characteristic (SPL) based on a frequency of a strain-insensitive stretchable thermoacoustic loudspeaker according to the present disclosure.

FIG. 7B is a diagram illustrating a sound pressure waveform over time in a 5 kHz operating condition of a strain-insensitive stretchable thermoacoustic loudspeaker according to the present disclosure.

FIG. 7C is a diagram illustrating a sound pressure waveform over time in a 13 kHz operating condition of a strain-insensitive stretchable thermoacoustic loudspeaker according to the present disclosure.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular articles "a" and "an" are intended to include the plural constitutes as well, unless the context clearly indicates otherwise. It will be further understood that the terms "comprise", "comprising", "include", and "including" when used in the present disclosure, specify the presence of the stated features, integers, operations, elements, and/or components, but do not preclude the presence or addition of one or more other features, integers, operations, elements, components, and/or portions thereof.

In addition, it will also be understood that when a first element or layer is referred to as being present "on" a second element or layer, the first element may be disposed directly on the second element or may be disposed indirectly on the second element with a third element or layer being disposed between the first and second elements or layers. It will be understood that when an element or layer is referred to as being "connected to", or "coupled to" another element or layer, it may be directly connected to, or coupled to the other element or layer, or one or more intervening elements or layers may be present therebetween. In addition, it will also be understood that when an element or layer is referred to as being "between" two elements or layers, it may be the only element or layer between the two elements or layers, or one or more intervening elements or layers may also be present.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” and the like should not be construed such that any aspect or design as described is superior to or advantageous over other aspects or designs.

In interpreting a numerical value, the value is interpreted as including an error range unless there is no separate explicit description thereof. In the context of the present disclosure, terms such as "about" may mean about ± 1%, about ± 2%, about ± 3%, about ± 4%, about ± 5%, about ± 6%, about ± 7%, about ± 8%, about ± 9%, or about ± 10% of the numerical value described in the present disclosure.

Further, the term 'or' means 'inclusive or' rather than 'exclusive or'. That is, unless otherwise stated or clear from the context, the expression that 'x uses a or b' means one of natural inclusive permutations.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

The strain-insensitive stretchable thermoacoustic loudspeaker according to the present disclosure comprises: a stretchable polymer substrate; a heating element including a film including bundles of vertically aligned carbon nanotubes (VACNTs) on the stretchable polymer substrate; an electrode part including a first electrode electrically connected to the heating element and a second electrode spaced apart from the first electrode and electrically connected to the heating element; and a power application means for applying alternating current (AC) voltage to the electrode part, wherein the AC voltage is applied to the electrode part such that the heating element thermally oscillates to generate an acoustic wave.

In the context of the present disclosure, the term "thermoacoustic loudspeaker" refers to a loudspeaker that periodically changes the temperature of air using a Joule heat effect and generates a sound wave accordingly. This thermoacoustic loudspeaker does not require a mechanical oscillation element such as a diaphragm, unlike a conventional mechanical oscillation loudspeaker, and has the advantage of being manufactured in a very thin and flexible form. In addition, the term "stretchable" means a property in which the substrate and the sound generator of the loudspeaker may be stretched by an external force, and the term "strain-insensitive" means a property in which sound pressure level performance degradation is minimized even when the loudspeaker is stretched.

A key feature of the strain-insensitive stretchable thermoacoustic loudspeaker of the present disclosure is that while the carbon nanotubes are integrated into the stretchable substrate, acoustic waves are generated through the carbon nanotubes (Vertically aligned carbon nanotubes, VACNT) aligned vertically on the substrate. In the inventive concept of the present disclosure, a portion of each of a plurality of VACNT strands is exposed to the outside out of the substrate while the remaining portion of each of the plurality of VACNT strands is fixedly buried in the substrate. This structure maximizes the contact area with air compared to the conventional stretchable thermoacoustic loudspeaker to improve heat transfer efficiency, and simultaneously maintains the continuity of the CNT network even while being stretched to minimize deterioration of the sound pressure level performance.

In the context of the present disclosure, "strand" refers to a unit of individual carbon nanotubes constituting the VACNT bundle, and "bundle" refers to a collection of a plurality of individual carbon nanotube strands formed on a substrate. That is, the "strand" refers to an individual CNT unit, and the "bundle" refers to a structure in which these CNT strands are gathered to form a network.

In the present disclosure, the "heating element" refers to a component that undergoes thermal oscillation when a voltage is applied thereto, thereby generating an acoustic wave. The heating element has a structure in which a portion of each of the carbon nanotube strands is embedded in the stretchable polymer substrate and the remaining portion thereof is exposed to the outside out of the substrate. This design maximizes the surface area in direct contact with the air and allows the generated heat to be quickly transferred along the CNT strands. In particular, due to the vertically aligned carbon nanotube (VACNTs) structure, the heat is effectively emitted into the air, thereby greatly improving thermoacoustic conversion efficiency compared to the conventional stretchable thermoacoustic loudspeaker.

In one embodiment, the exposed portions of the strands of the carbon nanotubes may be entangled with each other. This is to ensure electrical continuity by maintaining contact between the CNT strands even while being stretched, so that sound output performance is hardly deteriorated due to stretching. Accordingly, stable sound pressure level performance may be maintained while the stretchable thermoacoustic loudspeaker is highly stretched.

In an embodiment of the present disclosure, two electrodes are respectively attached to both opposing ends of the heating element and electrically contact the heating element. The AC current is applied thereto via the electrodes. The electrode may be made of a conductive paste so as to be stably coupled to the bundles of carbon nanotubes (VACNT). It is preferable that the electrode is constructed to maintain an electrical connection with the heating element even while being stretched.

When an alternating current (AC) voltage is applied to the heating element through the electrodes, the current flows into the VACNT bundle to generate Joule heat. At this time, while the current repeatedly changes the flow direction thereof according to the frequency of the AC voltage, a periodic temperature change occurs on the CNT surface. This temperature change locally fluctuates the density of air, thereby generating the sound wave. In particular, in the structure of the present disclosure, the CNT bundle has a wide contact area with air, such that the heat is rapidly transferred to secure high thermoacoustic conversion efficiency.

The stretchable polymer substrate may include a silicone elastomer. The stretchable polymer substrate according to the present disclosure is made of a material having high stretchability and restoring force, and thus the stretchable polymer substrate may allow the bonding between the substrate and the CNT bundle to be stably maintained even when the loudspeaker is stretched. Since the silicone elastomer has excellent mechanical flexibility and has a property of restoring to its original shape even through repeated deformation, the silicone elastomer may allow the structural stability of the heating element to be maintained even while being stretched, and thus is suitable for use as a material for the stretchable polymer substrate. Ecoflex may be used as an example of the silicone elastomer, and is one of the representative stretchable polymer materials with high stretchability and flexibility.

The electrode part may include a liquid metal or a solid metal, and may include both a liquid metal and a solid metal. The liquid metal may include one of gallium (Ga) and eutectic gallium-indium (EGaIn), and the solid metal may include one of gold (Au), silver (Ag), platinum (Pt), copper (Cu), aluminum (Al), iron (Fe), chromium (Cr), nickel (Ni), and alloys thereof. The electrode part made of such a metal material has excellent electrical conductivity, thereby achieving stable electrical contact with the CNT bundle and maximizing the operating efficiency of the loudspeaker. In particular, the liquid metal may be suitable to be applied to a device requiring stretchability and flexibility due to its unique fluidity and excellent electrical conductivity. In the case of the solid metal, silver (Ag) and copper (Cu) have high electrical conductivity, thereby having excellent signal transmission efficiency, and gold (Au) and platinum (Pt) have excellent oxidation resistance, thereby providing long-term stability. In addition, metals such as iron (Fe), chromium (Cr), nickel (Ni), and the like, and alloys thereof have excellent durability and may play a role of supplementing adhesion and stretchability under specific conditions.

The strain-insensitive stretchable thermoacoustic loudspeaker according to the present disclosure is designed so that structural deformation does not occur even in a state in which the strain-insensitive stretchable thermoacoustic loudspeaker is stretched by about 325%, thereby stably maintaining electrical connection between the heating element and the electrodes while the high stretchability is maintained.

In addition, the difference between a sound pressure level (SPL) in a state in which the strain-insensitive stretchable thermoacoustic loudspeaker is not stretched and the SPL in a state in which the strain-insensitive stretchable thermoacoustic loudspeaker is stretched by 150% is maintained at 5 dB or smaller. Thus, the sound output performance is hardly deteriorated even while being stretched. This is because the bundles of vertically aligned carbon nanotubes (VACNT) are firmly coupled to the substrate, and the CNT strands are entangled with each other to form a network structure, so that electrical continuity is maintained even while being stretched. This may effectively solve the problem of deteriorating the sound pressure level performance while being stretched that occurred in the conventional stretchable thermoacoustic loudspeaker.

Hereinafter, a method for manufacturing a strain-insensitive thermoacoustic loudspeaker according to the present disclosure will be described. The manufacturing method according to the present disclosure is characterized in that a low temperature transfer process is used.

The method for manufacturing the strain-insensitive stretchable thermoacoustic loudspeaker according to the present disclosure comprises: a first step of growing bundles of vertically aligned carbon nanotubes on a wafer; a second step of transferring the bundles of the vertically aligned carbon nanotubes onto a stretchable polymer substrate to form a heating element; a third step of removing the wafer from the bundles of the vertically aligned carbon nanotubes transferred to the stretchable polymer substrate; a fourth step of placing a first electrode and a second electrode onto the heating element so as to contact the heating element and to be spaced apart from each other, thereby forming an electrode part; and a fifth step of electrically connecting the electrode part and a power application means capable of applying an AC voltage thereto to each other.

The first step is a step of growing the bundles of the vertically aligned carbon nanotubes on the wafer, and in a subsequent step, a process of forming the CNT bundles to be transferred to the stretchable substrate is performed. In an embodiment of the present disclosure, a silicon wafer is used as the wafer. However, the scope of the present disclosure is not limited thereto as long as the wafer is a wafer made of a chemically stable material in the CVD process. Uniform growth and alignment of the bundles of the vertically aligned carbon nanotubes may be induced using the wafer.

The growth of the bundles of the vertically aligned carbon nanotubes in the first step may be performed by a chemical vapor deposition (CVD) process. The CVD process selectively grows the CNTs at high temperatures using carbon-based gas precursors and thus is able to form bundles of highly aligned CNTs.

The second step is a step of forming the heating element by transferring the bundles of the vertically aligned carbon nanotubes onto the stretchable polymer substrate, and corresponds to a process of transferring the VACNT bundles grown on the wafer in the first step to the stretchable polymer substrate. Since there is a risk that the substrate may be damaged due to high temperature when the CVD process is directly performed on the stretchable substrate, the method of the present disclosure adopts a scheme of effectively coupling the CNT bundles to the substrate using the low temperature transfer process.

In particular, in the transfer process of the present disclosure, a portion of the CNT strand is fixedly buried inside the polymer substrate, while the other portion thereof is exposed to the outside. This may increase heat transfer efficiency by maximizing the contact area with air, and may minimize the deterioration of sound pressure level performance by maintaining the CNT network even while being stretched. As a result, this step is a process of forming the heating element which is the core component of the loudspeaker, and in a subsequent step thereto, the electrode may be attached thereto to enable the sound output.

In the inventive concept of the present disclosure, in order to form the stretchable polymer substrate, a scheme of coating an uncured silicone elastomer on a stretchable silicone elastomer substrate may be applied. Since the uncured silicone elastomer has high viscosity, the bundles of carbon nanotubes may be easily attached thereto. Thus, the CNT bundles may be naturally buried or adhered to the uncured silicone elastomer, and then, as curing progresses, a stable bond between the substrate and the heating element may be formed.

In particular, the coating of the silicone elastomer may be performed using a spin coating process. The spin coating refers to a scheme of applying a liquid material on a substrate and then executing high-speed rotation to diffuse the applied liquid material to a uniform thickness. This scheme is advantageous for forming a thin and uniform silicone elastomer layer. Thus, the VACNT bundles may be effectively coupled to the polymer substrate, and the substrate may be optimized so that the transfer process of the CNT bundles thereto may be smoothly performed in the subsequent step.

The third step is a step of removing the wafer from the bundles of the vertically aligned carbon nanotubes transferred to the stretchable polymer substrate. In the previous step, the VACNT bundle was transferred to the stretchable polymer substrate. However, in this step, the wafer is still attached thereto. For this reason, a process of selectively removing the wafer in the third step so that only the CNT bundles remain on the stretchable substrate is performed.

A step of curing the uncured silicone elastomer immediately before removing the wafer may be further included in the method. This step is an essential process for effectively fixing the carbon nanotube (VACNT) bundles to the stretchable polymer substrate. In order to transfer the CNT bundle to the polymer substrate, it is necessary to maintain high viscosity and fluidity of the attached portion of the substrate using the uncured silicone elastomer. However, finally, the substrate and the CNT bundle should be firmly bonded to each other via the curing. If the wafer is removed without the curing, the CNT bundle is not completely fixed yet to the polymer substrate, so that there is a high possibility that a significant number of CNT strands are pulled out together or the alignment thereof may not be achieved such that the CNTs may collapse. Therefore, the CNT bundle is stably fixed to the polymer substrate only when the silicone elastomer is cured before removing the wafer, and thus, consistent structure and performance may be maintained in a subsequent process.

The fourth step is a step of placing a first electrode and a second electrode onto the heating element so as to contact the heating element and to be spaced apart from each other, thereby forming an electrode part. In this step, the electrodes are attached to both opposing ends of the heating element, respectively, to form an electrical connection therebetween. Thus, the current may flow along the CNT bundles. The electrode may be generally made of a conductive liquid metal (e.g., EGaIn, Ga, etc.) or a conductive solid metal (e.g., Ag, Au, Cu, etc.) or a conductive paste, and may maintain stable contact with the carbon nanotubes to effectively generate Joule heat when a voltage is applied thereto.

The fifth step is a step of electrically connecting the electrode part and a power application means capable of applying an AC voltage thereto to each other. In this step, a process of connecting the electrode part to an external power source so as to supply an electrical signal to the first electrode and the second electrode is performed. In general, the electrode part may be coupled to a wire, a lead wire, or an PCB circuit, and thus, the AC voltage may be stably transmitted to the heating element (VACNT bundles). When the AC voltage is applied to the heating element, the Joule heat is generated therefrom as the current flows along the CNT bundles. Thus, an acoustic wave is generated with a thermoacoustic effect.

Hereinafter, Examples of the present disclosure will be described. However, the Examples as described below are only some implementations of the present disclosure, and the scope of the present disclosure is not limited to the following Examples.

FIG. 1 is a diagram schematically showing a structure of a strain-insensitive stretchable thermoacoustic loudspeaker according to an embodiment of the present disclosure. The loudspeaker according to one embodiment of the present disclosure comprises: the heating element (sound output unit) embodied as the bundles of vertically aligned carbon nanotubes (VACNT); the stretchable polymer substrate (Ecoflex) supporting the heating element; and the electrode part (Ag paste).

As may be identified in FIG. 1, a portion of the VACNT strand is maintained to be exposed to the outside out of the substrate. Such a structure may serve to maximize a contact area with air, thereby increasing heat transfer efficiency and improving sound output. In addition, since the VACNT bundle is coupled to the stretchable substrate, the network is maintained even when being stretched, such that electrical and mechanical stability may be secured.

The first and second electrodes of the electrode part made of the Ag paste (silver paste) are respectively formed at both opposing ends of the heating element of the VACNT bundles. Thus, the current may flow through the VACNT bundles. When the power is applied thereto, and the AC voltage is transmitted through the electrodes, Joule heat is generated from the heating element as the current flows along the VACNT bundles. As this heat is transmitted to air, the sound is generated based on a thermoacoustic effect.

Based on such a structural design, the strain-insensitive stretchable thermoacoustic loudspeaker according to the present disclosure may be capable of minimizing deterioration in the sound pressure level performance while providing higher stretchability than the conventional stretchable loudspeaker.

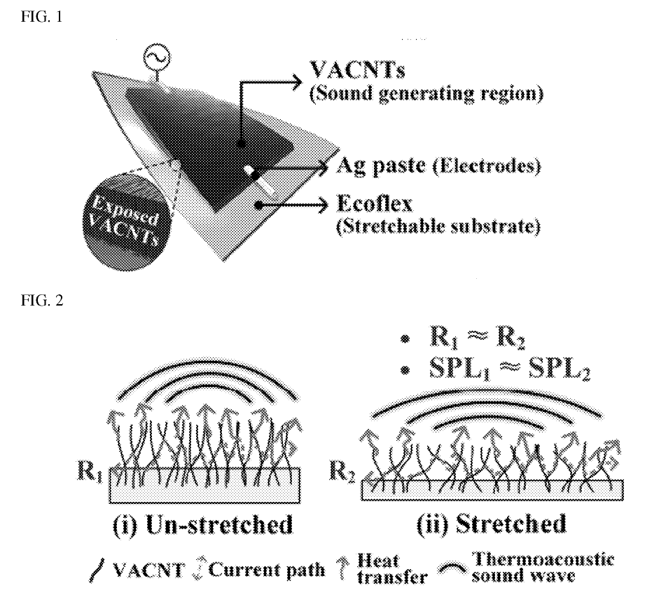

FIG. 2 is a diagram comparing operating mechanisms of the loudspeaker of the present disclosure respectively before and after stretching with each other.

In the pre-stretched state, the vertically aligned carbon nanotube (VACNT) bundles are stably disposed on the substrate. When the AC voltage is applied thereto through the electrodes, current flows along the CNT bundles to generate Joule heat. At this time, the generated heat is transferred to the air, such that a periodic temperature change induces a change in the air density to form a sound wave.

Even in the stretched state, the electrical continuity is secured while maintaining a network structure in which the CNT strands are entangled with each other. That is, the current may flow smoothly therein even while being stretched, so that the resistance R is not significantly changed (R₁≒R₂), and the sound pressure level performance SPL is also maintained constant (SPL₁≒SPL₂). In addition, as the alignment of the CNT strands is maintained, the heat transfer efficiency is not reduced, and thus the same level of the sound output as that before being stretched is achieved.

As a result, the stretchable thermoacoustic loudspeaker according to the present disclosure has a strain-insensitive characteristic in which the stretchable thermoacoustic loudspeaker maintains structural stability and sound pressure level performance even while being stretched, and may provide superior durability and performance compared to the conventional stretchable loudspeaker.

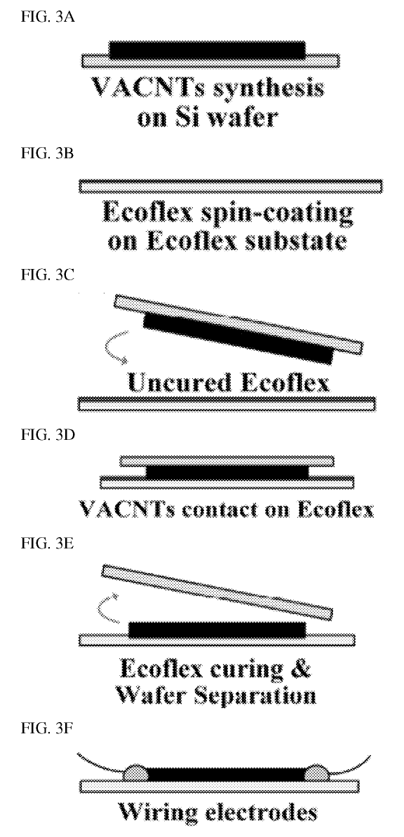

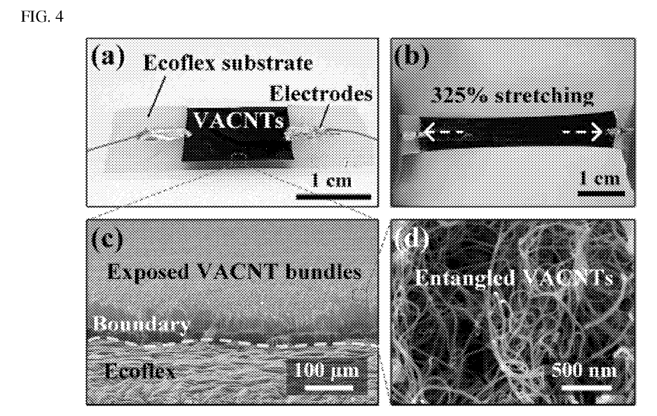

FIGS. 3A to 3F are diagrams illustrating a process for manufacturing a strain-insensitive stretchable thermoacoustic loudspeaker according to the present disclosure step by step.

First, the bundles of vertically aligned carbon nanotubes (VACNT) were grown on a silicon wafer using a chemical vapor deposition (CVD) process. In this way, the carbon nanotubes may be formed in the vertically aligned manner (VACNT), and may be grown in a bundle structure having a diameter of nanometer and a length of tens of micrometers (μm). The CNT bundle grown through the CVD process has a high alignment accuracy, and the CNT strands are entangled with each other inside the bundle, so that the network may be maintained even when being stretched.

In order to form the stretchable polymer substrate, Ecoflex in an uncured state was spin-coated on a Ecoflex substrate to form a uniform thin film. The spin coating process refers to a process in which a liquid-state silicone elastomer (Ecoflex) is applied to the surface of the substrate, and then the substrate is rotated at high speed to diffuse the applied liquid-state silicone elastomer to have a uniform thickness. In this process, Ecoflex constitutes a thin and uniform layer under a centrifugal force, and then, a curing process is performed thereon. Thus, a stable stretchable substrate is prepared. The uncured Ecoflex layer thus formed serves as an adhesive layer when the substrate is coupled to the bundles of carbon nanotubes (VACNT), and helps the bundles of CNTs to be effectively fixed to the substrate. In addition, since viscosity of the layer in the uncured state is high, such that the CNT bundle may be more stably attached thereto, and then structurally fixed thereto through a curing process.

While the Ecoflex is maintained in the uncured state, the VACNT bundles grown on the silicon (Si) wafer is brought into contact with the stretchable polymer substrate. Utilizing the viscosity of the uncured Ecoflex, the CNT bundles may be effectively attached to the polymer substrate. Since the Ecoflex has viscosity and fluidity in the uncured state, the CNT bundles may be naturally fixed to the substrate while the Ecoflex is being in close contact with the CNT bundle. At this time, a portion of the CNT strand is fixedly buried into the inside of the polymer substrate, while the remaining portion thereof is maintained in a state of being exposed to the outside. This structure maximizes the contact area of the CNTs with air, thereby increasing heat transfer efficiency and optimizing thermoacoustic performance.

Thereafter, a process of curing the Ecoflex is performed to allow the VACNT bundles to be stably attached to the stretchable polymer substrate, and then the Si wafer is removed to secure a state in which the CNT bundle has been completely transferred to the substrate. The curing process serves to firmly fix the CNT bundles to the Ecoflex by increasing the physical and mechanical stability of the Ecoflex. In general, a thermal curing or an air curing scheme may be used. In this way, the CNT bundle attached to the Ecoflex using viscosity in the uncured state may be firmly coupled to the substrate. In particular, when the wafer is removed in a state in which the curing is not completed, there is a high possibility that the CNT strands may be pulled out or collapse. Thus it is preferable to perform a wafer removal process after the curing. Thus, a structure in which the CNT bundles are stably coupled to the stretchable substrate while maintaining the alignment state of the CNT bundles may be formed.

Finally, the electrodes are respectively placed at both opposing ends of the heating element to form the electrical connection between the electrodes and the heating element. In general, the Ag paste (silver paste) or a metal electrode is used to make electrical contact with the carbon nanotubes. When a current is applied to the heating element through the electrodes, the current flows along the VACNT bundles, and the sound is generated under a thermoacoustic effect.

Such a manufacturing process may implement the strain-insensitive stretchable thermoacoustic loudspeaker in which the bundles of vertically aligned CNTs are stably coupled onto the stretchable substrate.

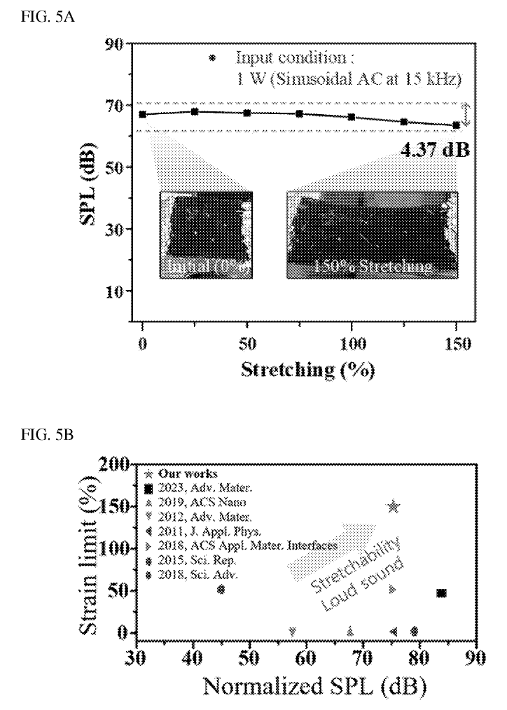

FIG. 4 is a view showing a real image of a strain-insensitive stretchable thermoacoustic loudspeaker manufactured according to an embodiment of the present disclosure and a SEM image obtained by photographing bundles of carbon nanotubes of a heating element thereof.

The upper left diagram of FIG. 4 shows the overall structure of the manufactured loudspeaker. Referring to the upper left diagram of FIG. 4, it may be identified that the vertically aligned carbon nanotube (VACNT) bundles are attached on the Ecoflex substrate. In addition, referring to the upper left diagram of FIG. 4, it may be identified that the structure in which the electrodes are respectively attached to both opposing ends of the heating element of the VACNT bundles such that current is applied to the heating element is secured.

The upper right diagram of FIG. 4 shows that structural deformation of the loudspeaker according to the present disclosure does not occur even when the loudspeaker according to the present disclosure is stretched by up to 325%. This means that the CNT bundles are firmly coupled to the polymer substrate, and the network structure is maintained even while being stretched. In general, in the conventional stretchable thermoacoustic loudspeaker, there is a problem in that the CNT bundle are cut off or the sound pressure level performance is degraded while being stretched. However, it may be identified that such performance degradation is minimized in the loudspeaker according to the present disclosure.

In a SEM image as the lower left diagram of FIG. 4, a state in which a portion of the CNT strand is buried inside the polymer substrate and the remaining portion thereof is exposed to the outside may be identified. It is shown that the boundary between the substrate and the CNT bundle is clearly defined, and the CNT bundles are stably fixed to the substrate even while being stretched. Such a structure plays an important role in maximizing the contact area of the heating element with the air to increase heat transfer efficiency, and to maximize thermoacoustic conversion performance.

In the lower right diagram of FIG. 4, a network structure in which individual CNT strands of the VACNT bundles are entangled with each other may be identified. This network structure may prevent deterioration of sound pressure level performance by maintaining electrical continuity of the CNT strands even while being stretched. In addition, the CNT strands are entangled with each other, such that a bonding force between the substrate and the CNT bundles is further strengthened, and mechanical stability thereof may be improved.

FIGS. 5A and 5B are diagrams showing experimental results proving that the strain-insensitive stretchable thermoacoustic loudspeaker according to the present disclosure maintains stable sound pressure level performance even while being stretched.

FIG. 5A is a diagram illustrating sound pressure level characteristics (SPL) in a state in which a strain-insensitive stretchable thermoacoustic loudspeaker according to the present disclosure is stretched by from 0% to 150%. In FIG. 5A, the change in the sound pressure level (SPL) based on the stretching (%) was measured. The experimental condition was as follows. The AC voltage (15 kHz sine wave) of 1 W was applied to the heating element, and the sound pressure levels at the initial state (0%) and a 150% stretched state were compared with each other. As a result of the experiment, it may be identified that a difference between the sound pressure level (SPL) in a state in which the strain-insensitive stretchable thermoacoustic loudspeaker is not stretched (at the initial state (0%)) and the SPL in a state in which the strain-insensitive stretchable thermoacoustic loudspeaker is stretched by about 150% is maintained within about 4.37 dB. This means that the problem of deteriorating the sound pressure level performance while being stretched that occurred in the conventional stretchable thermoacoustic loudspeaker is minimized in the stretchable thermoacoustic loudspeaker of the present disclosure. In addition, it may be visually identified through the inserted photo that the stretchable thermoacoustic loudspeaker of the present disclosure is stably maintained without structural deformation even after being stretched.

FIG. 5B is a diagram comparing sound pressure level characteristics and allowable strain limits of a strain-insensitive stretchable thermoacoustic loudspeaker according to the present disclosure and a stretchable loudspeaker reported in a previous study with each other. FIG. 5B shows that the loudspeaker (red asterisk) of the present disclosure shows excellent characteristics in stretchability and sound pressure level performance compared to conventional studies. The horizontal axis represents a normalized sound pressure level (dB), and the vertical axis represents a maximum strain limit (%). It may be identified that the loudspeaker according to the present disclosure maintains high SPL performance while having high stretchability of 150% or greater. In addition, compared with the conventional studies, a higher sound pressure level output is recorded in the loudspeaker according to the present disclosure under the same conditions (operating power, measurement distance, and frequency). This may be interpreted due to the fact that the heat transfer is more easily performed due to the carbon nanotube structure exposed to the air.

In conclusion, FIGS. 5A and 5B experimentally demonstrate that the loudspeaker according to the present disclosure may simultaneously implement excellent stretchability and high sound pressure level performance compared to the conventional technology.

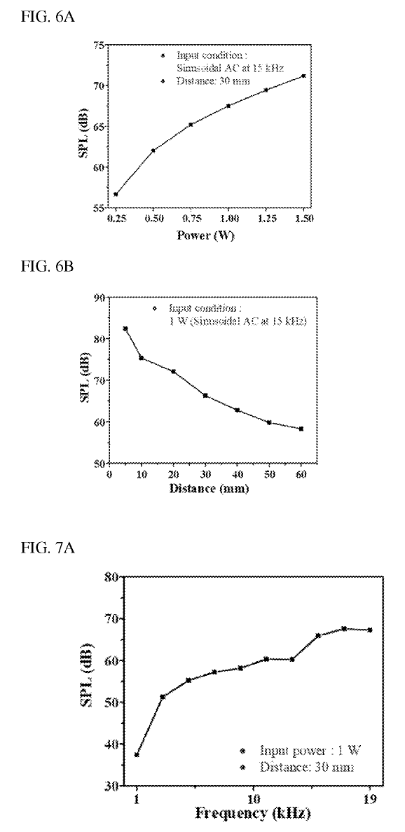

FIGS. 6A and 6B are diagrams illustrating a result of analyzing a sound pressure level SPL based on operating power and a measurement distance in order to evaluate sound pressure level characteristics of the strain-insensitive stretchable thermoacoustic loudspeaker of the present disclosure.

FIG. 6A is a diagram illustrating a sound pressure level characteristic (SPL) based on operating power of the strain-insensitive stretchable thermoacoustic loudspeaker according to the present disclosure. More specifically, FIG. 6A illustrates a change in a sound pressure level SPL based on an input power W. A sine wave (Sinusoidal AC) of 15 kHz was input to the heating element under an experimental condition, and the measurement distance was fixed at 30 mm. As a result of the experiment, as the input power increased, the SPL tended to increase linearly, and a sound pressure level of about 73 dB was recorded at the input of 1.5 W. This means that the output of the loudspeaker according to the present disclosure may be stably adjusted based on the input power. This indicates that the performance may be maintained even at a high output.

FIG. 6B is a diagram illustrating an evaluation of sound pressure level characteristics (SPL) based on a measurement distance of a strain-insensitive stretchable thermoacoustic loudspeaker according to the present disclosure. In FIG. 6A, the change in SPL based on the measurement distance mm was analyzed. Under an experimental condition, 1 W of power was applied to the heating element, and a sine wave of 15 kHz was used as the power. As a result of the measurement, it was identified that the SPL gradually decreased as the distance from the loudspeaker increased, and the acoustic characteristics decreased to about 85 dB at a distance of 10 mm and to about 55 dB at a distance of 60 mm.

In conclusion, FIGS. 6A and 6B suggest that the thermoacoustic loudspeaker according to the present disclosure may adjust the sound pressure level performance in a predictable manner based on the input power and the measurement distance, and may maintain a high sound output in a constant power range, thereby implementing basic characteristics of the loudspeaker.

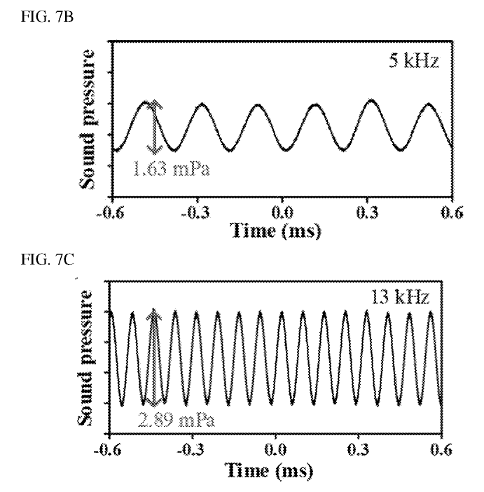

FIGS. 7A to 7C are diagrams showing experimental results of evaluating frequency characteristics of the strain-insensitive stretchable thermoacoustic loudspeaker of the present disclosure.

FIG. 7A is a diagram illustrating an evaluation of a sound pressure level characteristic (SPL) based on a frequency of a strain-insensitive stretchable thermoacoustic loudspeaker according to the present disclosure. In FIG. 7A, the change in the sound pressure level (SPL) based on the frequency (1 to 19 kHz) was measured. The experiment was conducted while maintaining the input power of 1 W and the measurement distance of 30 mm under the experimental condition. As a result, as the frequency increases, the SPL also tends to gradually increase, and a higher sound pressure level is recorded in the high frequency region. This means that due to the characteristics of the thermoacoustic loudspeaker, the heat transfer efficiency at high frequencies increases, such that the sound pressure level is stronger.

FIG. 7B is a diagram illustrating a sound pressure waveform over time in a 5 kHz operating condition of a strain-insensitive stretchable thermoacoustic loudspeaker according to the present disclosure. FIG. 7C is a diagram illustrating a sound pressure waveform over time in a 13 kHz operating condition of a strain-insensitive stretchable thermoacoustic loudspeaker according to the present disclosure.

In the graphs of FIGS. 7B and 7C, the sound pressure level waveforms at specific frequencies (5 kHz, 13 kHz) were analyzed. FIG. 7A illustrates the sound pressure waveform when a 5 kHz signal is applied, and FIG. 7C illustrates the sound pressure waveform when a 13 kHz signal is applied. This means that the constant output waveform and frequency is measured regardless of each of the waveform and the frequency of the input AC voltage.

In conclusion, FIGS. 7A to 7C experimentally demonstrate that the thermoacoustic loudspeaker according to the present disclosure provides stable acoustic performance in various frequency ranges, and in particular, may maintain high sound pressure level performance in a high frequency region.

Although the embodiments of the present disclosure have been described above with reference to the accompanying drawings, the present disclosure may not be limited to the embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that the embodiments as described above are not restrictive but illustrative in all respects.

What is claimed is:

1. A strain-insensitive stretchable thermoacoustic loudspeaker comprising:
a stretchable polymer substrate;
a heating element including a film including bundles of vertically aligned carbon nanotubes (VACNTs) on the stretchable polymer substrate;
an electrode part including a first electrode electrically connected to the heating element and a second electrode spaced apart from the first electrode and electrically connected to the heating element; and
a power application means for applying alternating current (AC) voltage to the electrode part,
wherein the AC voltage is applied to the electrode part such that the heating element thermally oscillates to generate an acoustic wave.

2. The strain-insensitive stretchable thermoacoustic loudspeaker of claim 1, wherein the stretchable polymer substrate includes a silicone elastomer.

3. The strain-insensitive stretchable thermoacoustic loudspeaker of claim 1, wherein the heating element is constructed such that a portion of each of the strands of the carbon nanotubes is buried in the stretchable polymer substrate, while the remaining portion thereof is exposed to the outside out of the stretchable polymer substrate.

4. The strain-insensitive stretchable thermoacoustic loudspeaker of claim 3, wherein the exposed portions of the strands of the carbon nanotubes are entangled with each other.

5. The strain-insensitive stretchable thermoacoustic loudspeaker of claim 1, wherein each of the first and second electrodes of the electrode part includes a liquid metal including one of gallium (Ga) and eutectic gallium-indium (EGaIn) or a solid metal including one of gold (Au), silver (Ag), platinum (Pt), copper (Cu), aluminum (Al), iron (Fe), chromium (Cr), nickel (Ni), and alloys thereof.

6. The strain-insensitive stretchable thermoacoustic loudspeaker of claim 1, wherein a structure of the strain-insensitive stretchable thermoacoustic loudspeaker is not deformed even in a state in which the strain-insensitive stretchable thermoacoustic loudspeaker is stretched by 325%,
wherein a difference between a sound pressure level (SPL) in a state in which the strain-insensitive stretchable thermoacoustic loudspeaker is not stretched and the SPL in a state in which the strain-insensitive stretchable thermoacoustic loudspeaker is stretched by 150% is maintained at 5 dB or smaller.

7. A method for manufacturing a strain-insensitive stretchable thermoacoustic loudspeaker, the method comprising:
a first step of growing bundles of vertically aligned carbon nanotubes on a wafer;
a second step of transferring the bundles of the vertically aligned carbon nanotubes onto a stretchable polymer substrate to form a heating element;
a third step of removing the wafer from the bundles of the vertically aligned carbon nanotubes transferred to the stretchable polymer substrate;
a fourth step of placing a first electrode and a second electrode onto the heating element so as to contact the heating element and to be spaced apart from each other, thereby forming an electrode part; and
a fifth step of electrically connecting the electrode part and a power application means capable of applying an AC voltage thereto to each other.

8. The method for manufacturing the strain-insensitive stretchable thermoacoustic loudspeaker of claim 7, wherein the first step of growing the bundles of the vertically aligned carbon nanotubes on the wafer is performed in a chemical vapor deposition (CVD) process.

9. The method for manufacturing the strain-insensitive stretchable thermoacoustic loudspeaker of claim 7, wherein the method further comprises providing the stretchable polymer substrate formed by coating an uncured silicone elastomer on a stretchable silicone elastomer substrate.

10. The method for manufacturing the strain-insensitive stretchable thermoacoustic loudspeaker of claim 9, wherein the coating of the uncured silicone elastomer on the stretchable silicone elastomer substrate is performed in a spin coating process.

11. The method for manufacturing the strain-insensitive stretchable thermoacoustic loudspeaker of claim 9, wherein the method further comprises curing the uncured silicone elastomer.

12. A strain-insensitive stretchable thermoacoustic loudspeaker manufactured by the method for manufacturing the strain-insensitive stretchable thermoacoustic loudspeaker of claim 7.
